(19) United States
(12) Patent Application Publication
(10) Pub. No.: US 2026/0095188 A1
(43) Pub. Date: Apr. 2, 2026

(54) ELECTRONIC CONTROL CIRCUIT

(71) Applicant: Logistics and Supply Chain MultiTech R&D Centre Limited, Pok Fu Lam (HK)

(72) Inventors: Feng Lu, Pok Fu Lam (HK); Jing Jung Tang, Pok Fu Lam (HK)

(21) Appl. No.: 18/901,365

(22) Filed: Sep. 30, 2024

(51) Int. Cl. H03L 7/197; H03L 7/093; H03L 7/099

(52) U.S. Cl. CPC H03L 7/1974; H03L 7/093; H03L 7/0992; H03L 2207/50

(57) ABSTRACT

An electronic control circuit. The circuit includes an oscillator circuit arranged to generate a periodic output signal having an output frequency equals to an input frequency multiplied by a fractional-N divider's division ratio; and a feedback circuit including an integer divider arranged to divide the periodic output signal with a positive integer and provide an integer divider output as a feedback signal to an input of the oscillator circuit; wherein the integer divider output is fed to the oscillator circuit as input periodic signal to a Time-Digital Convertor of the oscillator circuit; wherein the Time-Digital Convertor is arranged to output a digital signal based on an input reference signal with the input frequency and the input periodic signal.

### TECHNICAL FIELD

This invention relates to an electronic control circuit. Particularly, although not exclusively, the invention relates to a fractional Phase-Locked Loop control system.

### BACKGROUND OF THE INVENTION

A Phase-Locked Loop (PLL) is an electronic feedback control system which may be used in various applications involving signal synchronization, clock generation, frequency synthesis, and frequency modulation/demodulation. It is designed to track and align the phase and frequency of an input signal with a reference signal.

PLL may generates an output signal whose phase is aligned with the phase of an input signal, optionally with a different frequency in the output when compared to the input signal, such as a clock signal. PLLs are useful in various applications such as clock synchronization in digital circuits, frequency synthesis for generating stable frequencies, demodulation in communication systems and signal recovery from noisy channels.

### SUMMARY OF THE INVENTION

In accordance with a first aspect of the present invention, there is provided an electronic control circuit comprising: an oscillator circuit arranged to generate a periodic output signal LO having an output frequency equals to an input frequency f_{ref} multiplied by a fractional-N divider's division ratio FCW; and a feedback circuit including an integer divider arranged to divide the periodic output signal LO with a positive integer and provide an integer divider output as a feedback signal to an input of the oscillator circuit; wherein the integer divider output is fed to the oscillator circuit as input periodic signal DIV to a Time-Digital Convertor (TDC) of the oscillator circuit; wherein the TDC is arranged to output a digital signal T based on an input reference signal REF with the input frequency f_{ref} and the input periodic signal DIV.

In accordance with the first aspect, the electronic control circuit is a fractional all digital Phase-Locked Loop (PLL) control system.

In accordance with the first aspect, the oscillator circuit comprises the TDC for receiving the input reference signal REF, an oscillator for generating the periodic output signal LO, and a loop filter therebetween.

In accordance with the first aspect, the fractional-N divider's division ratio FCW is a combination of an integer part FCW[int] and a fractional part FCW[frac].

In accordance with the first aspect, the fractional-N divider's division ratio FCW is a rational number greater than or equal to 1.

In accordance with the first aspect, the circuit further comprises a clock correction stage arranged to covert a digital signal T outputted from a Time-Digital Convertor (TDC) based on the input reference signal REF with the input frequency f_{ref} and an input periodic signal DIV, which is divided from LO by a ratio equals to the integer part FCW[int] of the fractional-N divider's division ratio FCW, to a modified digital signal TC representing an output from the TDC based on the input frequency and a summation of the integer part FCW[int] and the fractional part FCW[frac] of the fractional-N divider's division ratio FCW; wherein T Is associated with a first time difference Δt₁ between a rising edge of input signals REF and DIV; and wherein the modified digital signal TC is further provided to the oscillator in the oscillator circuit for generating the periodic output signal LO.

In accordance with the first aspect, the integer divider is arranged to process the periodic output signal LO with the integer part FCW[int] of the fractional-N divider's division ratio FCW, wherein the integer part FCW[int] equals to floor of FCW being rounded down to the nearest integer that is less than or equal to the fractional-N divider's division ratio FCW.

In accordance with the first aspect, the clock correction stage includes an adder and a clock correction calculator module arranged to determine a clock correction digital signal C associated with a second time difference Δt₂ between a virtual reference clock signal (VRC) and the input periodic signal DIV, and wherein the adder is arranged to output the modified digital signal TC=T+C.

In accordance with the first aspect, the virtual reference clock signal (VRC) has the first rising edge align with a rising edge of the input reference signal REF, and the frequency of the virtual reference clock signal equals to the targeted frequency f_{divt} of the input periodic signal DIV after a reset of the electronic control circuit.

In accordance with the first aspect, the electronic control circuit further comprises a master reset arranged to be activated by a low-active digital reset signal.

In accordance with the first aspect, the clock correction calculator module is further arranged to determine the clock correction digital signal C based on an integer REC, which equals to a count of rising edge of DIV between a current rising edge of REF CLK and the last rising edge of REF, outputted by TDC.

In accordance with the first aspect, a value of C equals to C[i] at the number i rising edge of REF after reset, where i is positive integer serial number, and C[i] is generated as follows:
for I=1, C[1] is 0; and
for I>1,
(1) if REC equals to 1,

$$C [ i + 1 ] = C [ i ] + \frac{FCW [ frac ] \times {T}_{DCOt}}{u} ;$$

(2) if REC equals to 0,

$$C [ i + 1 ] = C [ i ] + \frac{FCW \times {T}_{DCOt}}{u} ;$$

(3) if REC is greater than 1,

$$C [ i + 1 ] = C [ i ] + \frac{( FCW - REC \times Fcw [ int ] ) \times {T}_{DCOt}}{u} ;$$

wherein u is unit time used for quantization for the TDC, Δt₁=T×u and Δt₂=TC×u;
wherein T_{divt}=FCW[int]×T_{DCOt}, f_{DCOt}=FCW[int]×f_{divt}, T_{ref}=FCW×T_{DCOt}, f_{DCOt}=FCW×f_{divt}, f_{DCOt} denotes a targeted frequency of periodic output signal LO and T_{DCOt} denotes a corresponding period, f_{divt} denotes a targeted frequency of DIV and T_{divt} denotes a corresponding period, f_{ref} denotes a targeted frequency of REF and T_{ref} denotes a corresponding period.

In accordance with a first aspect, the electronic control circuit further comprises a coarse tune module arranged to provide a coarse tune output signal DCT to control switching of capacitors in the oscillator in the oscillator circuit to tune the periodic output signal LO coarsely.

In accordance with a first aspect, the coarse tune output signal DCT is an accumulation of inputs CCT provided by the clock correction calculator module.

In accordance with a first aspect, the modified digital signal TC is filtered by the loop filter before further provided to the oscillator.

In accordance with a first aspect, the oscillator includes a digitally controlled oscillator.

### BRIEF DESCRIPTION OF THE DRAWINGS

Embodiments of the invention will now be described, by way of example, with reference to the accompanying drawings in which:

FIG. 1 is a block diagram of an example PLL incorporating a ΣΔ fractional-N divider.

FIG. 2 is a block diagram of an electronic control circuit in accordance with an embodiment of the present invention.

FIG. 3 is a diagram illustrating waveforms of a clock signal, a virtual refence clock signal and a master reset signal involved in an example operation of the electronic control circuit of FIG. 2.

FIG. 4 is a block diagram of an electronic control circuit in accordance with an alternative embodiment of the present invention.

### DETAILED DISCLOSURE OF THE INVENTION

The inventors, through their experiments and trials, devised that an All Digital Phase-Locked Loop (ADPLL) is a type of PLL that employs digital signal processing techniques to implement the various components of a PLL using digital circuits. Instead of using analog components like voltage-controlled oscillators and analogue phase detectors, preferably, an ADPLL may rely on digital signal processing blocks such as digital phase detectors, digital filters, and Digitally Controlled Oscillators (DCOs) to achieve the desired functionality. ADPLLs offer advantages such as flexibility, reconfigurability, and better noise performance compared to analog PLLs. They may be used in wireless communication systems, frequency synthesis applications, and clock recovery circuits.

Without wishing to be bound by theory, implementing a fractional-N frequency synthesis technique in the ADPLL involves using a digital divider or a fractional-N divider to divide the output frequency. The fractional-N divider allows for fractional division ratios, enabling the generation of a fractional output frequency.

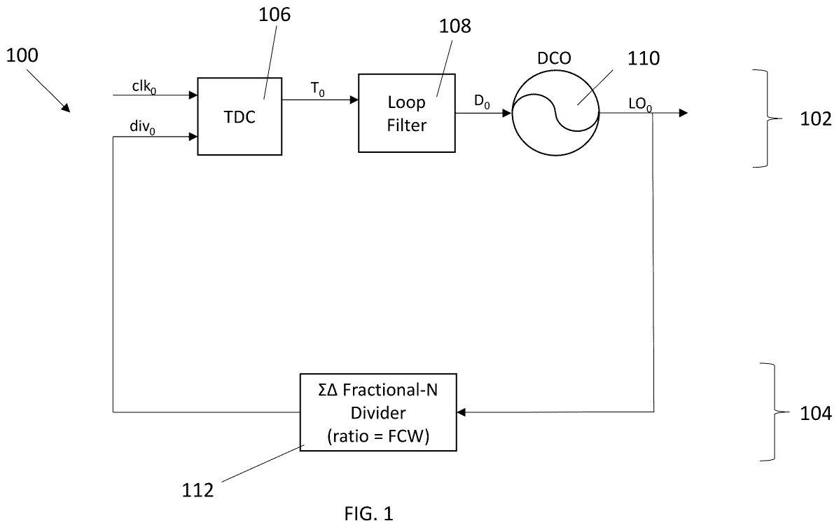

With reference to FIG. 1, there is shown an example embodiment of a PLL 100, which include some key components in it, such as an oscillator circuit 102 including a phase detector (or phase/frequency detector, PFD) 106, a loop filter 108, a Digitally Controlled Oscillator (DCO) 110, in addition, a feedback circuit 104 for providing a feedback signal to the phase detector.

The PLL may operate as follows. Firstly, a stable reference signal or a clock signal is provided to the PFD 106, the PFD compares the phase and frequency of the reference signal with the divided DCO output signal DIV, and generates an error signal based on the phase difference. Then, the error signal may be converted to a current which may be further filtered by a loop filter 108, such as a low pass filter or a band pass filter, to produce a control voltage. Finally, the control voltage adjusts the DCO frequency output by the DCO 110. The DCO output is divided by the ZA fractional-N divider in the feedback loop 104. The ΣΔ modulator dynamically changes the division ratio to achieve a fractional division, allowing for finer frequency resolution.

In this example, the fractional-N ADPLL comprises a ΣΔ fractional-N divider 112 in the feedback loop 104, in which the dividing ratio is FCW. The input signal of this ΣΔ fractional-N divider is LO₀, and the output signal is DIV₀.

For non-integer FCW, it may be implemented by switching the dividing ratio between at least 2 integers. This makes the cycle of the divider's output signal DIV₀ vary all the time, thus may induce large noise to Time-Digital Convertor (TDC) which operates as the phase/frequency detector of the PLL.

For example, the electronic control circuit may be used to generate a clock signal of 2.55 GHz from a 100 MHz reference clock. Using an integer-N PLL, it may be limited to integer multiples of the reference frequency, such as 2 GHz or 3 GHz. However, with a fractional(-N) PLL, the desired 2.55 GHz may be produced, with the following parameters:
Clock/Reference Frequency CLK/REF: 100 MHz
Desired Output Frequency LO/F_{DCOt}: 2.55 GHZ
Division Ratio (N): 25.5 (fractional)

In an example operation, as ΣΔ modulator in the feedback loop may alternate the division ratio between 25 and 26 in such a way that the average division ratio is 25.5, resulting in the desired output frequency. Accordingly, the fractional allows the division ratio to be a non-integer value, providing the flexibility to achieve the exact desired frequency, which facilitates generations of frequency signals with fine frequency resolution that are not integer multiples of the reference clock, which may be used in applications requiring precise frequency synthesis, such as wireless communication systems.

For PLLs use integer-N dividers, which can only divide by whole numbers. Fractional-N dividers, however, allow for non-integer division ratios, providing finer frequency resolution. This may be achieved by periodically switching between different integer division ratios, so the average division ratio over time is fractional. To control the switching between integer division ratios, a Sigma-Delta modulator is used such that the frequency divider becomes fractional. It converts the fractional division ratio into a sequence of integers that, when averaged, approximate the desired fractional value.

Fractional PLLs may be useful in applications such as wireless communication in which PLL may be used in frequency synthesizers for generating precise carrier frequencies. It may also be used as clock generation which provides high-resolution clock signals for digital circuits. In some alternative examples, fractional PLLs may be used in signal processing which helps in applications requiring precise frequency control and low phase noise.

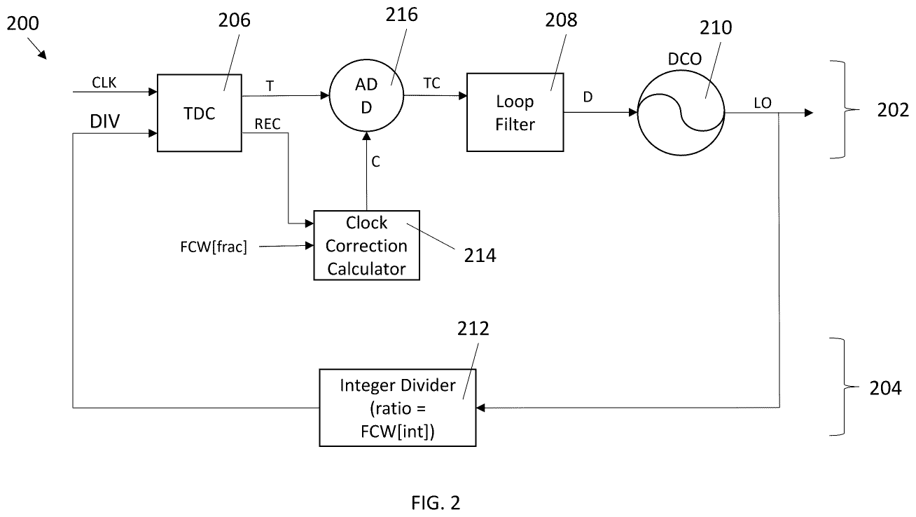

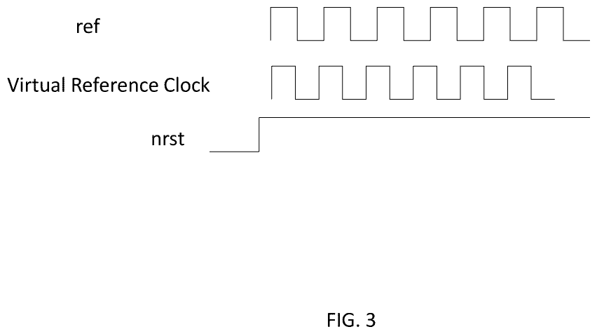

With reference to FIGS. 2 and 3, there is shown embodiments of an electronic control circuit comprising: an oscillator circuit arranged to generate a periodic output signal LO having an output frequency equals to an input frequency f_{ref} multiplied by a fractional-N divider's dividing ratio FCW; and a feedback circuit including an integer divider arranged to divide the periodic output signal LO with a positive integer and provide an integer divider output as a feedback signal to an input of the oscillator circuit; wherein the integer divider output is fed to the oscillator circuit as input periodic signal DIV to a Time-Digital Convertor (TDC) of the oscillator circuit; wherein the TDC is arranged to output a digital signal T based on an input reference signal REF with the input frequency f_{ref} and the input periodic signal DIV.

In this embodiment, the electronic control circuit is a fractional all digital Phase-Locked Loop (PLL) control system. The circuit comprises three main parts, namely the oscillator circuit arranged to generate a periodic output signal LO, based on the input clock signal or reference signal and the divider signal, a feedback loop that feeds the output LO back to the input end, i.e. the TDC, after certain processing of the output signal which help the system to tune or optimize the frequency of LO if necessary, and a clock correction module for providing correct voltage control signal to the Voltage Controlled Oscillator (VCO) or Digitally Controlled Oscillator (DCO) as shown in the figure. The signal conversion in the oscillator circuit will be further explained later in this disclosure.

For example, with a fractional(-N) PLL, the desired 2.55 GHz may be produced, with the following parameters:
Clock/Reference Frequency CLK/REF: 100 MHz
Desired Output Frequency LO/F_{DCOt}: 2.55 GHZ
Division Ratio (N): 25.5 (fractional)

Instead of using as ΣΔ modulator in the feedback loop which may alternate the division ratio between 25 and 26 in such a way that the average division ratio is 25.5, resulting in the desired output frequency, a integer divider with a fixed division ratio 25 is used to divide the oscillator's output signal LO, a fixed division ratio 25.5 is input in the register for generating the desired 2.55 Ghz signal at the output.

The terminology used herein Is for the purpose of describing particular embodiments only and is not intended to be limiting to the invention. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this invention pertains. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

The functional units and modules of the electronic control circuit, such as the integer divider and the clock correction calculation module in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

Referring to FIG. 2, there is shown a first preferred embodiment of the present invention. In this example, the electronic control circuit 200 comprises the TDC 206 for receiving the input reference signal REF, a Digitally Controlled Oscillator (DCO) 210 for generating the periodic output signal LO, and a loop filter 208 therebetween, in the oscillator circuit 202. DCO is short for Digitally Controlled Oscillator. The frequency of its periodic output signal LO is digitally controlled by a digital signal named D. Loop Filter 208 is a low pass digital filter. Its input signal is a digital signal named TC. Its output signal is a digital signal named D. Preferably, its gain for DC input signal is infinite. The Loop Filter 208 may use REF as clock, thus its output signals update on the rising edge of CLK.

In this example, Time-Digital Convertor (TDC) 206 is the input end of the oscillator circuit 202. Its input signals are a reference clock named REF in this disclosure, and a periodic signal named DIV which is divided from LO. Its function is to detect the phase difference between REF and DIV, e.g. by quantifying the time difference (represent by Δt₁) between the rising edges of the input signals, converting the difference/error to a digital signal T. Preferably, the TDC 206 quantifies Δt₁ between a rising edge of REF and the last rising edge of DIV before this rising edge of REF.

Preferably, the relation between Δt₁ and T may be

$$T = \frac{Δ {t}_{1}}{u} ,$$

where u is unit time used for quantization. In this disclosure, T denotes the digital signal, but also represents the signal's numerical value. Although T might be in various format, e.g. signed floating-point number, signed integer, some customized digital format, etc., we neglect the format, and only focus on its numerical value mathematically. This principle applies to any digital signal in this disclosure.

In addition, T is a signed numerical value and it may be assigned with negative sign when the rising edge of DIV is ahead of the corresponding rising edge of REF, or positive vise versa. If the unit time u is properly chosen, T is a signed integer, which is easy to save in register.

Similar to TDC 206, the Loop Filter 208 may also use REF as clock. Their output signals update on rising edge of REF. As described earlier, the loop filter 208 may be a low pas filter or a band pass filter which filter undesired frequency signals from TDC 206, i.e. TC in the embodiment as shown in FIG. 2, before it is used as control signal for controlling the operation of the DCO 210 or VCO at the output end of the oscillator circuit 202.

Preferably, as for the feedback loop 204, an integer divider 212 is included to process the periodic output signal LO with the integer part FCW[int] of the fractional-N divider's division ratio FCW, wherein the integer part FCW[int] equals to floor of FCW being rounded down to the nearest integer that is less than or equal to the fractional-N divider's division ratio FCW. Preferably, the fractional-N divider's division ratio FCW is a combination of an integer part FCW[int] and a fractional part FCW[frac], and is a rational number greater than or equal to 1. For example, if the FCW=2.5, FCW[int]=2, and FCW[frac]=0.5 such that FCW=FCW[int]+FCW[frac].

In this preferred embodiment, the electronic control circuit 200 further comprising a clock correction stage arranged to covert, or compensate, a digital signal T outputted from a Time-Digital Convertor (TDC), to TC which is further filtered before being fed to the DCO 210 for generating LO, referring to FIG. 2. In this example, T, the error signal is generated based on the input reference signal REF with the input frequency f_{ref} and an input periodic signal DIV, to a modified digital signal TC representing an output from the TDC 206 based on the input frequency and a summation of the integer part FCW[int] and the fractional part FCW[frac] of the fractional-N divider's division ratio FCW; wherein T is associated with a first time difference Δt₁ between a rising edge of input signals REF and DIV; and wherein the modified digital signal TC is further provided to the oscillator 210 in the oscillator circuit for generating the periodic output signal LO.

Preferably, the clock correction stage comprises an adder 216 and a clock correction calculator module 214 arranged to determine a clock correction digital signal C associated with a second time difference Δt₂ between the Virtual Reference Clock (VRC) and a reference clock signal, and wherein the adder is arranged to output the modified digital signal TC=T+C.

In this example, ADD is an adder 216 which implement a logical/mathematical operation—adding. It uses REF as clock. Its output signal updates on rising edge of REF.

Preferably, f_{DCOt} may be defined to be targeted frequency of LO, and f_{ref} may be defined to be frequency of reference clock, where FCW is their frequency ratio, thus

$$FCW = \frac{{f}_{DCOt}}{{f}_{ret}} ,$$

and f_{DCOt}=FCW×f_{ref}. For a fractional-N ADPLL, FCW is a positive rational number greater than or equal to 1.

In this preferred embodiment, an integer divider 212 is used instead of the ΣΔ fractional-N divider. The input signal of this integer divider 212 is LO, and the output signal is DIV. The Clock Correction Calculator module 214 is provided to make the dividing ratio of LO and REF equivalent to the fractional number FCW.

For the integer divider 212, the dividing ratio is FCW[int], which is integer part of FCW, also called flooring of FCW mathematically. By define f_{divt} to be targeted frequency of DIV,

$$FCW [ int ] = \frac{{f}_{DCOt}}{{f}_{divt}} , and {f}_{DCOt} = FCW [ int ] \times {f}_{divt} .$$

Preferably, the reference clock signal is a virtual reference clock signal having the first rising edge align with a rising edge of the input reference signal REF, and the virtual reference clock signal includes a targeted frequency f_{divt} of the input periodic signal DIV after a reset of the electronic control circuit.

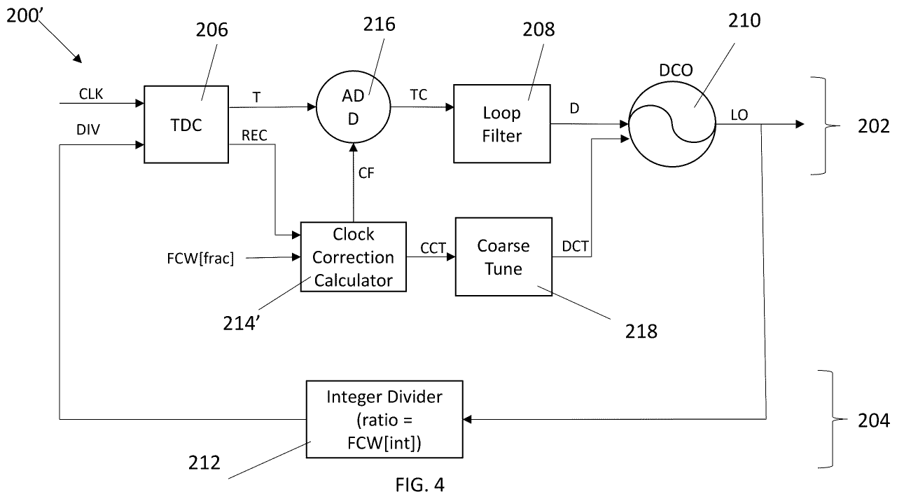

Since f_{divt} is different from f_{ref}, the rising edge of DIV cannot lock with the rising edge of REF, thus the frequency of DIV may not be as same as targeted, and the frequency of LO is not as same as targeted either. To solve that, the Virtual Reference Clock is introduced, referring to FIG. 4. Preferably, the Virtual Reference Clock is an imaginary signal in a mathematical process. The Virtual Reference Clock may be utilized by calculating where its rising edges are if it really existed.

Referring to FIG. 4, the Virtual Reference Clock is defined as follows, firstly, after reset, its first rising edge align with the first rising edge of ref, secondly, its frequency equals to f_{divt}. The signal nrst is a low-active digital reset signal for the ADPLL. If the rising edge of DIV lock with the rising edge of the Virtual Reference Clock, DIV has a frequency exactly as same as targeted, so does LO.

As described earlier, the signal T is quantified from the time difference Δt₁ between the rising edges of REF and DIV. To make LO have targeted frequency, the signal TC fed into Loop Filter may be quantified from the time difference Δt₂ between the rising edges of Virtual Reference Clock and the input periodic signal DIV. The Clock Correction Calculator module is arranged to calculate TC with T. The output signal of Clock Correction Calculator is a digital signal named C.

In addition, TDC 206 has an extra function—counting the rising edge/edges of DIV between the current rising edge of REF and the last rising edge of REF, outputting the counting result as an integer named REC. TC can be calculated by TC=T+C.

Preferably, the clock correction calculator module 214 calculates C based on the input FCW[frac] and the value of REC provided by TDC 206. Defining C[i] to be the value of C at the number i rising edge of ref after reset, where i is positive integer serial number. C[i] is generated as follows:
for i=1, C[1] is 0;
At any rising edge of ref other than the first one, i.e. for i>1,
(1) if REC equals to 1,

$$C [ i + 1 ] = C [ i ] + \frac{FCW [ frac ] \times {T}_{DCOt}}{u} ,$$

wherein FCW[frac] is fractional part of FCW, defined by FCW[frac]=FCW−FCW[int];
(2) if REC equals to 0,

$$C [ i + 1 ] = C [ i ] + \frac{FCW \times {T}_{DCOt}}{u}$$

(3) if REC is greater than 1,

$$C [ i + 1 ] = C [ i ] + \frac{( FCW - REC \times Fcw [ int ] ) \times {T}_{DCOt}}{u} .$$

With reference to FIG. 4, there is shown a second embodiment of the electronic control circuit 200′ of the present invention. In this embodiment, the ADPLL 200′ further comprises a coarse tune module 218 arranged to provide a coarse tune output signal DCT to control switching of capacitors in the oscillator 210 in the oscillator circuit 202 to tune the periodic output signal LO coarsely, in which the coarse tune output signal DCT is an accumulation of inputs CCT provided by the clock correction calculator module 214′.

The ADPLL 200′ in this second embodiment is similar to the first embodiment, in which all the modules except Clock Correction Calculator 214′ and Coarse Tune 218 are as the same. In this Clock Correction Calculator 214′, C is calculated following the method mentioned above, and is further divided into two parts, i.e. CF and CCT, where C=CF+CCT. These two parts are also digital signals, CF is used as input of Loop Filter, and CCT is used as input of Coarse Tune 218.

Preferably, a positive numerical threshold named TH is chosen, e.g.

$$TH = \frac{FCW \times {T}_{DCOt}}{u} ,$$

then CF and CCT are calculated as follows:
CCT=TH×k; and
CF=C−CCT, where k is floor of

$$\frac{C}{TH} , i . e . rounding \frac{C}{TH}$$

down to the nearest integer that is less than or equal to the it.

Preferably, the module Coarse Tune 218 accumulates its input signal and use the results as its output signal DCT, which may be used to control switching of a group of capacitors in DCO 210, to tune the DCO's frequency coarsely.

These embodiments may be advantageous in that, the fractional PLL with fixed division ratio may be realized by including an integer divider in the feedback loop process a fixed integer divider, and the error signal is further processed by the correction module to embed the fractional part in it. This would allow precise frequency synthesis, which is crucial in applications like wireless communication, or applications which require frequencies that are not integer multiples of the reference frequency being generated.

Advantageously, the electronic control circuit is not intuitive and has great difference from the traditional PLL. In addition, unlike digital PLL employing ΣΔ modulator which is needed in ΣΔ fractional-N divider, the noise induced by the divider is greatly reduced, so is the noise at the output node of TDC (Time-Digital Converter). Thus, the noise of the whole ADPLL is reduced.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

Any reference to prior art contained herein is not to be taken as an admission that the information is common general knowledge, unless otherwise indicated.

1. An electronic control circuit comprising:
an oscillator circuit arranged to generate a periodic output signal LO having an output frequency equals to an input frequency f_{ref} multiplied by a fractional-N divider's division ratio FCW; and
a feedback circuit including an integer divider arranged to divide the periodic output signal LO with a positive integer and provide an integer divider output as a feedback signal to an input of the oscillator circuit;
wherein the integer divider output is fed to the oscillator circuit as input periodic signal DIV to a Time-Digital Convertor (TDC) of the oscillator circuit; wherein the TDC is arranged to output a digital signal T based on an input reference signal REF with the input frequency f_{ref} and the input periodic signal DIV.

2. The electronic control circuit in accordance with claim 1, wherein the electronic control circuit is a fractional all digital Phase-Locked Loop (PLL) control system.

3. The electronic control circuit in accordance with claim 2, wherein the oscillator circuit comprises the TDC for receiving the input reference signal REF, an oscillator for generating the periodic output signal LO, and a loop filter therebetween.

4. The electronic control circuit in accordance with claim 3, wherein the fractional-N divider's division ratio FCW is a combination of an integer part FCW[int] and a fractional part FCW[frac].

5. The electronic control circuit in accordance with claim 4, wherein the fractional-N divider's division ratio FCW is a rational number greater than or equal to 1.

6. The electronic control circuit in accordance with claim 4, further comprising a clock correction stage arranged to covert a digital signal T outputted from a Time-Digital Convertor (TDC) based on the input reference signal REF with the input frequency f_{ref} and an input periodic signal DIV, which equals to the integer part FCW[int] of the fractional-N divider's division ratio FCW, to a modified digital signal TC representing an output from the TDC based on the input frequency and a summation of the integer part FCW[int] and the fractional part FCW[frac] of the fractional-N divider's division ratio FCW; wherein T is associated with a first time difference Δt₁ between a rising edge of input signals REF and DIV; and wherein the modified digital signal TC is further provided to the oscillator in the oscillator circuit for generating the periodic output signal LO.

7. The electronic control circuit in accordance with claim 6, wherein the integer divider is arranged to process the periodic output signal LO with the integer part FCW[int] of the fractional-N divider's division ratio FCW, wherein the integer part FCW[int] equals to floor of FCW being rounded down to the nearest integer that is less than or equal to the fractional-N divider's division ratio FCW.

8. The electronic control circuit in accordance with claim 6, wherein the clock correction stage includes an adder and a clock correction calculator module arranged to determine a clock correction digital signal C associated with a second time difference Δt₂ between a virtual reference clock signal and the input periodic signal DIV, and wherein the adder is arranged to output the modified digital signal TC=T+C.

9. The electronic control circuit in accordance with claim 8, wherein the virtual reference clock signal has the first rising edge align with a rising edge of the input reference signal REF, and the virtual reference clock signal includes a targeted frequency f_{divt} of the input periodic signal DIV after a reset of the electronic control circuit.

10. The electronic control circuit in accordance with claim 9, further comprising a master reset arranged to be activated by a low-active digital reset signal.

11. The electronic control circuit in accordance with claim 9, wherein the clock correction calculator module is further arranged to determine the clock correction digital signal C based on an integer REC, which equals to a count of rising edge of DIV between a current rising edge of REF and the last rising edge of REF, outputted by TDC.

12. The electronic control circuit in accordance with claim 11, wherein:
a value of C equals to C[i] at the number i rising edge of REF after reset, where i is positive integer serial number, and C[i] is generated as follows:
for i=1, C[1] is 0; and
for i>1,
(1) if REC equals to 1,
$$C [ i + 1 ] = C [ i ] + \frac{FCW [ frac ] \times {T}_{DCOt}}{u} ;$$
(2) if REC equals to 0,
$$C [ i + 1 ] = C [ i ] + \frac{FCW \times {T}_{DCOt}}{u} ;$$
(3) if REC is greater than 1,
$$C [ i + 1 ] = C [ i ] + \frac{( FCW - REC \times Fcw [ int ] ) \times {T}_{DCOt}}{u} ;$$
wherein u is unit time used for quantization for the TDC, Δt₁=T×u and Δt₂=TC×u;
wherein T_{divt}=FCW[int]×T_{DCOt}, f_{DCOt}=FCW[int]×f_{divt}, T_{ref}=FCW×T_{DCOt}, f_{DCOt}=FCW×f_{divt}, f_{DCOt} denotes a targeted frequency of periodic output signal LO and T_{DCOt} denotes a corresponding period, f_{divt} denotes a targeted frequency of DIV and T_{divt} denotes a corresponding period, f_{ref} denotes a targeted frequency of REF and T_{ref} denotes a corresponding period.

13. The electronic control circuit in accordance with claim 11, further comprising a coarse tune module arranged to provide a coarse tune output signal DCT to control switching of capacitors in the oscillator in the oscillator circuit to tune the periodic output signal LO coarsely.

14. The electronic control circuit in accordance with claim 13, wherein the coarse tune output signal DCT is an accumulation of inputs CCT provided by the clock correction calculator module.

15. The electronic control circuit in accordance with claim 6, wherein the modified digital signal TC is filtered by the loop filter before further provided to the oscillator.

16. The electronic control circuit in accordance with claim 3, wherein the oscillator includes a digitally controlled oscillator.
